(19) United States
(12) Patent Application Publication
(10) Pub. No.: US 2021/0334424 A1
(43) Pub. Date: Oct. 28, 2021

(54) METHOD AND APPARATUS FOR LAYING OUT A WINDOW STRUCTURE

(71) Applicant: Salamander Industrie-Produkte Gmbh, Turkheim (DE)

(72) Inventor: Till Schmiedeknecht, München (DE)

(73) Assignee: Salamander Industrie-Produkte Gmbh, Türkheim (DE)

(21) Appl. No.: 17/243,198

(22) Filed: Apr. 28, 2021

(30) Foreign Application Priority Data
Apr. 28, 2020 (DE) 10 2020 111 572.5

(51) Int. Cl. G06F 30/13; G06F 30/12

(52) U.S. Cl. CPC G06F 30/13; G06F 30/12

(57) ABSTRACT

In a method for laying out a window structure on a construction project, a compass direction of at least one building side of the construction project is detected, window areas of window structure associated with building sides of the construction project are determined, and design parameters of the window structure are calculated based on the collected data and a database of windows. The calculation of the design parameters may include optimizing a lighting situation of the construction project.

### CROSS REFERENCE TO RELATED APPLICATIONS

This patent application claims priority to German Patent Application No. 10 2020 111 572.5, filed Apr. 28, 2020, which is incorporated herein by reference in its entirety.

### BACKGROUND

### Field

The disclosure relates to a method for laying out a window structure on a construction project. The construction project may be an old building, which is already provided with a window structure, or a new building, in which the window structure may not yet exist or may be incomplete.

### Related Art

The window structure is typically laid out during an inspection of the construction project, e.g. by an architect or an intermediary specialized in windows. This procedure for laying out the window structure is time-consuming, since the architect or intermediary must be on site together with the builder and all windows of the window structure must be individually recorded and laid out. In addition, it has been found that in practice the design is often not optimal, especially if the design is not carried out by specially trained personnel.

In connection with the effort to maximally optimize energy consumption and at the same time guarantee high comfort of living, common methods often turn out to be insufficient.

US 2014/0214473 A1 describes a method and a system for providing a sales and marketing tool in which a mobile terminal, such as a smartphone, can be used to record, track and retrieve information relating to a building and building elements provided therein. However, it has been found that the sales and marketing tool described in US 2014/0214473 A1 cannot yet be used to provide an optimal design of window structures on construction projects.

### BRIEF DESCRIPTION OF THE DRAWINGS/FIGURES

The accompanying drawings, which are incorporated herein and form a part of the specification, illustrate the embodiments of the present disclosure and, together with the description, further serve to explain the principles of the embodiments and to enable a person skilled in the pertinent art to make and use the embodiments.

FIG. 1 shows a schematic diagram of a detection of a compass direction of a building side and other information of a construction project.

FIG. 2 shows a schematic illustration of a capture of further information of a window of a construction project.

FIG. 3 shows a schematic illustration of a mobile device for collecting information of a construction project comprising a noise level, according to an exemplary embodiment.

FIGS. 4A-C show various representations of a user interface of a mobile device for capturing information of a construction project comprising a climate zone, and windows on building sides, according to exemplary embodiments.

FIG. 5 shows a user interface of another mobile device, which is used in particular to detect a noise situation, according to an exemplary embodiment.

The exemplary embodiments of the present disclosure will be described with reference to the accompanying drawings. Elements, features and components that are identical, functionally identical and have the same effect are—insofar as is not stated otherwise—respectively provided with the same reference character.

### DETAILED DESCRIPTION

In the following description, numerous specific details are set forth in order to provide a thorough understanding of the embodiments of the present disclosure. However, it will be apparent to those skilled in the art that the embodiments, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring embodiments of the disclosure. The connections shown in the figures between functional units or other elements can also be implemented as indirect connections, wherein a connection can be wireless or wired. Functional units can be implemented as hardware, software or a combination of hardware and software.

An object of the present disclosure is to address the disadvantages of conventional systems, including to provide an alternative method and device with which the design of a window structure on a construction project can be carried out simply, precisely and reliably.

In an exemplary embodiment, a computer-implemented method is provided for laying out a window structure on a construction project. The method includes:
capturing a compass direction of at least one building side of the construction project,
capturing of window areas of the window structure assigned to building sides of the construction project, and
calculating design parameters of the window structure based on the collected data and a database of windows, wherein the calculation of the design parameters includes optimizing a lighting situation of the construction project.

This method may be performed with a mobile device, e.g. a smartphone or a tablet computer. The capture of the compass direction can be done by a compass, e.g. by a user standing with the mobile device in front of a building side and storing the compass orientation associated to the building side.

It is understood that compass direction herein includes not only as north, east, south, west, but may also refer to a value in between, e.g., an angular orientation 10° east of the north orientation.

In other embodiments, it may be provided that the detection of the compass direction is not, or at least not only, performed by a compass of the mobile device: Instead, a geographic coordinate may be determined using a satellite navigation system (e.g. GPS or Galileo). Furthermore, a map service (e.g., Google Maps) can be used to detect that the determined geographic coordinate is located, for example, immediately in front of the north-facing side of a building. Thus, the compass direction of a building side can be determined from the floor plan of the building stored in the map service.

Calculating design parameters based on collected data and a database may include determining one or more windows from the database that can be used to optimize a target parameter, such as the lighting situation. Thus, the calculated design parameters may include a type designation of a window.

In one embodiment of the method for laying out a window structure on a construction project, it is provided that the lighting situation comprises an assignment of the net glass areas to cardinal/compass directions, wherein the optimization of the lighting situation of the construction project comprises minimizing a deviation of the assignment of the net glass areas to a predetermined ideal distribution, wherein the predetermined ideal distribution comprises, in particular, a predetermined ideal assignment of net glass areas to cardinal directions, e.g. to South, North, West and East.

For example, a given ideal distribution might include 50% of the total window area on the south side, 20% each of the total window area on the east and west sides, and 10% of the total window area on the north side. If an existing window structure of the construction project has less than 50% of the total window area on the south side, an optimization could include, e.g., proposing window structures without bars on the south side to increase the window area percentage and thus get closer to the 50%.

More generally, an objective function can be defined that takes on a larger value the greater the deviation of the assignment of window areas to cardinal directions from the ideal distribution.

In one embodiment of the method for laying out a window structure on a construction project, it is provided that the method further comprises the steps of:
capturing a building class of the construction project from a predetermined list of building classes that includes: single-family house, semidetached house, terraced end house, terraced middle house, multi-family house with less than 6 dwelling units, and/or multi-family house with at least 6 dwelling units, and/or
capturing a construction period of the building,
   wherein the method further comprises determining the building class and/or the construction period based on a digital image of the construction project.

Based on the building class, for example, an adapted energy calculation or calculation of the light situation can be made. Based on this energy calculation or calculation of the light situation, the window proportions can then be determined accordingly.

The building period can also be used in the energy calculation. For example, if no other information about insulation values of the building is available, default values for the respective construction period can be used. This has the advantage that an initial estimate of the energy situation can be made quickly without the user having to know concrete insulation values of the building.

The building period can also be used to make an initial estimate of the lighting situation. Furthermore, it plays a role in the selection of windows that fit the style of the building.

In addition to the building period, other building characteristics can be queried, such as: house type, living area, floors, material of existing window frames, glazing, GPS orientation of the house, number of windows per side of the house, window types, number of bars and dimensions of the windows. In addition, an actual as well as target light situation can be captured.

In one embodiment of the method for designing a window structure on a construction project, it is provided that calculating the design parameters further comprises optimizing a regional preference situation, wherein in particular the database comprises a mapping between windows and a regional preference.

By considering the location data (e.g., climate zone, burglary statistics, regional preference etc.) as the first level, a query of the building characteristics as the second level, and finally a query of the specific customer requirements (e.g., individual design preferences), the determination of the window to be suggested can be represented as a three-level model. The information from all three levels can be stored locally on the mobile device or in a central database in the cloud. Similarly, the window finally selected by the user from a database of windows can be stored in the cloud. Another application running on a different terminal device may then be designed to query the stored window selection.

Based on all the information, a suitable window can then be suggested. Here, on the one hand, the local climate can be used for energy calculation and, on the other hand, a connection to regionally typical profile systems can be established via a separate database.

In one embodiment of the method for laying out a window structure on a construction project, it is provided that the method further comprises:
capturing geographic coordinates of the construction project,
determining climatic parameters based on the geographic coordinates, wherein the climatic parameters are determined in particular by assigning the geographic parameters to one of several climatic zones,
   wherein the calculation of the design parameters is performed taking into account the climatic parameters, wherein the climatic parameters comprise in particular an annual temperature distribution and/or an annual solar radiation distribution.

This embodiment has the advantage that location-dependent climatic parameters can be taken into account, and thus a window structure can be designed that is optimally adapted to the local conditions with regard to the energy situation and lighting conditions. In particular, one or more of the location-dependent variables wind load, sun hours, sun angle, radiation, and temperature difference can be taken into account. In particular, these variables can also be present as time-of-day-dependent curves and be taken into account in the calculation of a target function.

For example, for Germany, an assignment of the geographic coordinates of the construction project to one of the 16 climate zones in Germany can be provided. The user can be shown a comparison of the German average with his climate zone. He can further get a statement about his energy cost savings depending on the selected system compared to the old windows presented on the mobile device.

For example, in the case of a high temperature difference, averaged over the day, between the usual room temperature and the outdoor temperature, which depends on the time of day, particularly well insulated windows can be proposed.

Based on the geographic coordinates of the construction project, burglary statistics related to the region in which the construction project is located can also be identified and considered. For example, in a region that is at risk for burglaries, burglar-resistant windows can be specifically suggested.

In exemplary embodiments, the method comprises a step of optimizing an objective function. In other words, the window is proposed with whose characteristics an optimum for the objective function is obtained.

For example, the objective function can be a weighted sum. The summands of this sum can include, for example an energy summand, indicating how advantageous this window structure is from an energy point of view, and a cost summand, indicating how high the cost of this window structure is. Weighting factors in front of these two so-called can then indicate whether the cost or the energy rating of the window structure is more important to the user. Thus, an example objective function can be represented as follows:

Score=w₁S₁+w₂S₂+ . . .

“Score” is hereby the value of the objective function for a given window, w₁ is the weighting factor for the first summand, and S₁ is the unweighted first summand. For example S₁ be the expected annual heating energy in kWh using the window design. The second summand S₂ can be the purchase and/or installation cost of the window structure in Euros. Depending on the choice of weights w₁ and w₂ different window structures will lead to an optimal (here: low) value of the objective function and thus be suggested by the method as an ideal window.

At least one of the summands of the objective function takes a lighting situation into account, such that at least one lighting situation is also optimized in the result. The lighting situation can, for example, be included as part of the energy optimization.

In an exemplary embodiment, the procedure can read in energy costs and thus determine on its own how acquisition costs are to be weighted relative to the energy situation. For example, the weighting factor for the acquisition costs can be set relative to the weighting factor for the energy evaluation such that the savings expected in the next 20 years due to a better energy situation are weighted equally in total to the higher acquisition costs.

In further exemplary embodiments, additional summands may be provided, for example a summand whose amount depends on how well the window structure fits stylistically with the building. Again, an associated weighting factor may be provided so that the user can adjust the extent to which acquisition costs, energy optimization, and stylistic considerations are to be taken into account in the design of the window structure by appropriate selection of the weighting factors.

In one embodiment of the method for designing a window structure on a construction project, it is provided that optimizing the lighting situation comprises:
calculating net glass areas associated with building sides of the construction project, and/or
calculating a ratio of net glass area to a floor area of the construction project and/or a number of stories of the construction project.

In one embodiment of the method for laying out a window structure on a construction project, it is provided that the method further comprises:
taking a digital image of one side of the building of the construction project, and
automatically identifying one or more windows in the digital image, including estimating the glass area, in particular the net glass area, of the one or more windows.

The window may also be a window recess in the building, e.g., a shell building. It may be provided that identifying the windows in the digital image comprises determining a total window area, wherein determining comprises providing each of the windows with at least two reference markers, generating a digital image of the window with the at least two reference markers; and determining the dimensions, in particular an allowance, comprising height and/or width of the window based on the digital image.

In an exemplary embodiment, the window can be provided with reference markers in at least two characteristic locations. In an exemplary embodiment, at least two reference markers can be reversibly attached, in particular glued, to the window.

In an exemplary embodiment, it can be provided that a shape of the window corresponding to the digital image of the window is detected and the dimensions are determined on the basis of the detected shape. In an exemplary embodiment, it may be provided that the shape of the window is detected using a graphical user interface, such as a touch display of a mobile terminal, such as a tablet PC or a smartphone, wherein the graphical user interface represents the digital image and registers a user input related to the shape of the window, wherein in particular the graphical user interface further represents a reference geometry corresponding to the shape of the window, such as a quadrilateral, in particular a rectangle.

In an exemplary embodiment, it may be provided that a perspective information corresponding to the digital image of the window is further registered and the dimensions are determined on the basis of the perspective information.

In an exemplary embodiment, it can be provided that at least one further window depicted on the digital image, such as at least one window or at least one door, is detected, and the dimensions, in particular a dimension, of the at least one further window are determined on the basis of the digital image.

This has the advantage that the user does not have to manually enter the information about the windows of the construction project, but this information can be captured in which the user orientates a camera of a mobile device, such as a smartphone or tablet computer, to the construction project.

Automatic identification of one or more windows in the image captured by the camera can be done, for example, by a neural network trained with photos of buildings and window areas marked in them.

In alternative embodiments, it can be provided that the mobile device has a 3D recording device such as a LIDAR. Thus, recesses and deepenings in the building surface can be identified automatically. These recesses and deepenings are at least possibly provided for window surfaces. Thus, it can be provided that these identified recesses and/or deepenings are displayed to the user and the user can select whether this is really a window surface. Thus, a semi-automatic method is provided with which an efficient detection can be achieved with high accuracy at the same time.

In one embodiment of the method for laying out a window structure on a construction project, it is provided that the method further comprises:
outputting a first user prompt to prompt a user to move a mobile device to a horizontal orientation, and/or
outputting a second user prompt to prompt the user to move the mobile device to a vertical orientation.

Outputting the user prompts has the advantage that the user is guided through the operating steps and thus incorrect operations can be avoided.

After the initial user prompt, the user places the mobile device in a horizontal orientation, which is often most appropriate for determining an orientation relative to north using a compass provided in the mobile device.

The second user prompt asks the user to place the mobile device in a vertical orientation, which is often best for taking a photo with a camera provided on the back of the mobile device.

By outputting the first user prompt and the second user prompt (e.g. in close succession), for example within ten seconds, preferably within three seconds, it can be ensured that the sky orientation recorded in the horizontal orientation and the image recorded in the vertical orientation correspond to an identical or barely changed position of the user.

In a further embodiment of the method for designing a window structure at a construction project, it is provided that the method further comprises detecting a noise level in the interior and/or exterior of the construction project, in particular using a microphone of the mobile device, wherein calculating the design parameters comprises optimizing a noise situation of the construction project.

This has the advantage that, in addition to the lighting situation and an energy optimization, an optimization with regard to a noise situation can also take place at the same time.

In particular, it may be provided that an objective function to be optimized, based on which a proposed window design is determined, comprises a summand reflecting a noise situation. In particular, the summand may be proportional to a noise level at a location within the building. Thus, it can be taken into account that a particular window design may be energetically advantageous, but may not provide quite as good acoustic insulation values.

In an exemplary embodiment, it can be provided that a weighting of the noise summand is the higher, the higher a noise level detected by the microphone is in the exterior of the construction project. Thus, a sound-insulating effect of a window structure can be taken into account the more, the higher a noise level in the outside area of the building is.

In an exemplary embodiment, the noise level is adjusted here based on a time of day and/or a day of the week on which the noise level was recorded. For example, if a high noise level has already been recorded on a weekend morning, this can be taken into account more than if a high noise level has been recorded on a weekday morning, i.e. during the expected rush hour.

In advantageous embodiments, it can be provided that different types of noise are distinguished. For example, it can be provided that car noise is recognized as such and then particularly sound-insulating window structures are suggested. This can be implemented, for example, by selecting a weighting factor for the noise summand particularly high if car noise or car noise with a noise level above a certain limit value has been detected.

In one embodiment of the method for laying out a window structure on a construction project, it is provided that the detection of the noise level is carried out using a geo-database on noise sources, in particular using a map service with information on a course and/or a traffic load of roads.

The expected noise level caused by a road can be estimated, for example, based on the width of the road or on a traffic intensity on the road queried by a map service. This has the advantage that a measurement with a microphone is no longer necessary.

In one embodiment of the method for laying out a window structure on a construction project, it is provided that the method further comprises:
detecting a microphone fault situation, in particular a situation of a microphone covered by a hand of a user, and
outputting a prompt signal to a user to prompt the user to correct the microphone error situation.

This has the advantage of avoiding erroneous (too low) noise levels being recorded by a covered microphone.

In one embodiment of the method for laying out a window structure on a construction project, it is provided that the method further comprises performing a normalization of the noise picked up by a microphone of the mobile device, wherein the normalization is performed in particular by assigning types of mobile devices to noise sensitivities of the mobile devices.

In a further embodiment, it is provided that the method further comprises determining an optimal ventilation frequency. In particular, a combination of one or more of the following information can be used to determine an optimal ventilation frequency: geographic coordinates, individual information about the area, rooms, desired temperature, position of windows, usual ventilation position and number of persons. In an exemplary embodiment, all of the above information is taken into account. The information can be entered, for example, by the user via a graphical user interface. Likewise, the determined optimal ventilation frequency can be displayed on the user interface.

In particular, ventilation frequency can be optimal in terms of energy savings, pollen count, severe weather, and/or burglary protection.

The optimal ventilation frequency can be determined as a weighted function of the optimal ventilation frequencies for each aspect.

The optimal ventilation frequency can be calculated as a number (e.g. two times per day) or optimal ventilation times can be determined, e.g.: it can be determined that ventilation should take place between 09:00 and 10:00 and between 15:00 and 16:00.

To determine the optimal ventilation times, ideal ventilation times can be determined for each individual aspect and these can be summed up or weighted and taken into account to determine the overall optimal ventilation times. For example, it could be specified that under the aspect of burglary protection, ventilation should ideally only take place during the day. From the aspect of pollen protection, ventilation should only take place between 06:00 and 08:00 in the city, and between 19:00 and 24:00 in rural areas. Whether the building is located in the city or in a rural area can be determined using geographical coordinates and a map service such as Google Maps. With regard to the aspect of energy saving, ideally ventilation can only be carried out during the day or in the afternoon, when the outside temperatures are not too high. With regard to the aspect of protection against severe weather, it can be recommended to ventilate only when a weather forecast (e.g., retrieved from an internet server) predicts no rain or only a small amount of precipitation, e.g., a predicted amount of precipitation lower than a certain threshold.

Thus, the optimal ventilation times can be automatically based not only on the fixed information entered once, but can also take into account current information such as rainfall, wind speed, outdoor temperature, indoor temperature, pollen count, pollutant concentration in the air, CO2 content in the building and other information.

For example, it can be provided that at a certain CO2 content, for example above 1000 ppm, it is always suggested to ventilate. The CO2 content can be determined via suitable sensors in the building, or it can be provided that the mobile device queries the information about the CO2 content from a networked smart home system. For example, the mobile device can be implemented as an app on a smartphone and the smartphone can connect to the smart home system via WLAN.

Further information, for example one or more of rainfall, wind speed, outside temperature, pollen count and pollutant concentration in the air can be retrieved via the internet from suitable information services and is thus available to the minute. For this purpose, the geographical coordinates of the building can be sent to a central server, which then sends the information on these coordinates to the mobile device. Alternatively, the calculation of the optimum ventilation times can also be performed on the central server.

The optimal ventilation time can be determined as the ventilation times at which all individual conditions are met. Alternatively, a sum for ventilation recommendations can be determined for each period. For example, it can be determined that between 06:00 and 08:00 it is recommended to ventilate from three aspects, and thus this represents a total recommended ventilation time. In other words, it can be determined when the number of ventilation time recommendations for different aspects is greater than a threshold. The summation of individual recommendations may be weighted. For example, a user may enter that pollen protection and/or burglary protection are particularly important and thus these should be given special weighting. In this case, it could be provided that the weighted sum of the individual recommendations for a certain time period must be greater than a limit value so that this time is recommended as the optimal ventilation time.

When determining the ventilation times, the method can take into account whether the windows can only be tilted, and thus only allow a small air flow, or whether the windows can be opened completely. If the windows are only tiltable, a longer opening time may be recommended for the optimal opening times. For example, the method may include a step of determining a maximum total airflow based on the maximum window opening conditions and suggesting the optimal opening duration such that a complete exchange of air in the living space is possible under usual wind conditions. Thus, for many windows that can only be tilted, there is a low total airflow and thus an optimal long opening time, and for many windows that can be fully opened, there is a high total airflow and thus an optimal shorter opening time.

In an exemplary embodiment, the method provides for outputting a user prompt at the time of a recommended ventilation time, for example when a recommended ventilation time period starts. The user prompt may be, for example, a beep and/or a vibration signal from a mobile device. Thus, the user is reminded to ventilate.

The desired temperature can be taken into account in such a way that whenever the ambient temperature (measured or predicted) is closer to the desired temperature than the current indoor temperature, ventilation is recommended.

To avoid unnecessarily bothering the user with user prompts, it may further be provided that the method queries information about an opening state of the windows from a smart home system. For example, opening sensors may be attached to the windows that detect the opening state of the window and transmit this information to a central unit of the smart home system. This information may in turn be queried by the mobile device from the central unit, and it may be provided that the mobile device outputs a user prompt only when there is a recommended exposure time, but the windows are not open, or the number of open windows is below a predetermined threshold.

In exemplary embodiments, it can be provided that an electronic signal is output during the optimal ventilation time to control a ventilation controller to bring one or more windows into a ventilation position. For example, this signal can be transmitted by radio, in particular via WLAN. Thus, an automatic control of the windows can be carried out at the optimal ventilation times and it can be ensured that there is always optimal ventilation. In particular, ventilation can be carried out in the early morning hours without the occupants having to get up early.

The ventilation control can be configured such that, e.g. if burglary protection is prioritized, ventilation only takes place when the occupants are present, which can be detected e.g. via infrared sensors.

In a further embodiment, it is provided that the method comprises that further data relating to the construction project are recorded. These data and the use of the app itself also allow conclusions to be drawn about the customer types. In particular, the recorded data can be enriched by further information based on databases, e.g. a database on a server (e.g. Property values, purchasing power indicators, regional construction costs, further market data, data from construction regulations, comparison with data from other projects in the app) and can be prepared in a further processing step such that, e.g. on a server to which the data relating to the construction project are transmitted, the request can be qualified.

It is possible to centrally record the customer request or the construction project corresponding thereto and to rank it according to the qualification. In particular, specific processing strategies can be proposed in this case. The processing can then be systematized by an interface into a CRM system or an integrated CRM module. It is therefore possible for the window seller or fitter to concentrate on the most suitable projects and to correctly process the customer requests according to their potentials. It is also possible to increase a profit for the seller.

The qualification of the construction project can be determined on the basis of a customer qualification (e.g. financial potential and/or involvement of the customer) and/or by the type of project (e.g. Project scope and/or urgency). Therein, the ranking, i.e. the prioritization of the construction projects, can be carried out on the basis of a systematic recording of types of projects and customer types.

In particular, a project qualification can be carried out on the basis of the dimension urgency and/or the dimension “potential project volume”.

It is possible to determine the (potential) project volume on the basis of one or more of the following information: calculation basis (Flex B), calculation potential (proposed combination), additional potential—new building or complete conversion, in which window areas can be enlarged if exposure values are suboptimal, special topics (front door, HST) RC 2/3, sun protection, roller shutters, interest in surfaces.

The urgency can be determined on the basis of one or more of the following information: coordination with other constructions (new building, complete renovation (facade and heating)) or the presence of currently leaking windows. A low urgency can be assumed in the case of an energetic optimization only of windows and/or the replacement of individual windows.

The method can comprise recording one or more of the above-mentioned information on a mobile apparatus and transmitting it from the mobile apparatus to a central server.

A customer qualification can be carried out along the dimensions of financial potential and/or involvement. In this case, the financial potential can be identified on the basis of one or more of the following information: property type (multi-family house, single-family house, terraced house, semi-detached house), property values for postcodes, purchasing power on the basis of postcodes (e.g. based on destatis). In particular, for this purpose, e.g. a building type, a postcode or other location information (e.g. coordinate) can be recorded on the mobile apparatus. By way of example, a recording of the location information can be recorded by a sensor for a navigation satellite system.

An involvement of the customer can be determined by one or more of the following information: duration of use of the app, detailing of inputs, selection of variants and/or investment (multi-family house) or property used on its own.

In particular, a prioritization can be carried out by weighted summation of one or more values such as square meter number, property value, construction costs, location factor, relative window costs and/or project costs, in order to determine a rating and to determine a ranking of a plurality of construction projects on the basis of the rating.

Projects can be adapted according to project size and can be prioritized in a manner scaled by location factor and relative project size. In particular, the method can comprise recording usage parameters, in particular a usage duration of the user when recording the information, and transmitting them to the server. It is therefore also possible for the usage parameters to be taken into account when processing the construction project.

In an exemplary embodiment, the method furthermore comprises that the server transmits the recorded construction projects to one or more mobile target apparatuses for informing a window seller and/or fitter. In particular, the transmission to the target apparatuses can be carried out in an order based on the rating of the construction projects.

In an exemplary embodiment, the mobile target apparatus has a notification module in order to inform the window seller and/or fitter of the construction project received. In particular, the notification can be carried out when a particularly high rating, e.g. on the basis of a high determined urgency, is present, in particular with an urgency higher than a predefined threshold urgency. It is therefore possible to provide a technical solution which ensures that urgent projects are processed quickly.

Further, the disclosure provides a mobile device for laying out a window structure on a construction project, comprising:
a cardinal direction detection interface (cardinal direction detector, or compass direction detector) for detecting a cardinal direction of at least one building side of the construction project,
a window area capture interface of window areas of the window structure assigned to building sides of the construction project, and
calculating design parameters of the window structure based on the collected data and a database of windows, wherein the calculation of the design parameters includes optimizing a lighting situation of the construction project.

In one embodiment of the mobile device for laying out a window structure at a construction project, it is provided that the compass direction detection interface comprises a compass, the window area detection interface comprises a digital camera, and/or the device further comprises a microphone detecting a noise level in the interior and/or exterior of the construction project.

Furthermore, the present disclosure provides a system, comprising a mobile device as mentioned above, and a server, wherein the mobile device is configured to transfer captured information and/or usage parameters to the server, and wherein the server is configured to perform a prioritization of construction projects based on the captured information and/or usage parameters. In an exemplary embodiment, the prioritization can be transferred to a mobile target device and/or a construction project based on the prioritization.

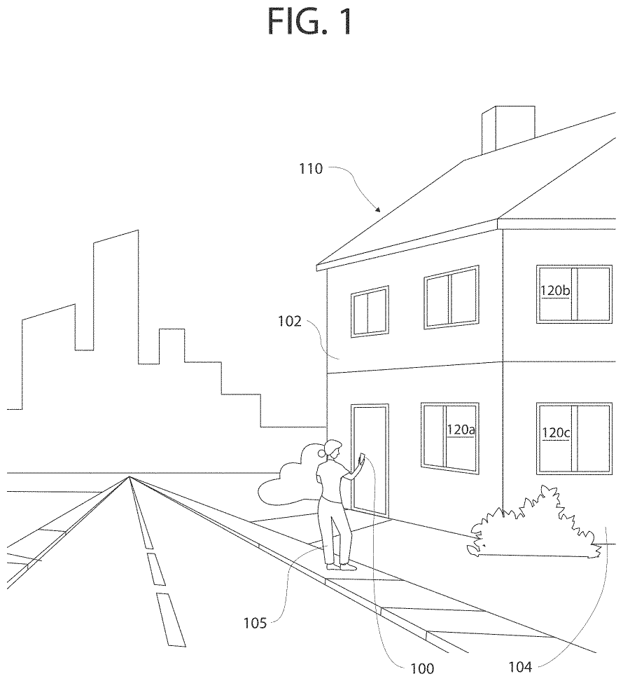

FIG. 1 is a schematic representation of a detection of a compass direction of a building side and other information of a construction project. A construction project 110, in this case a building 110 that has already been completed and is to be renovated, is located adjacent to a road. A front side 102 of the building faces the street. A person 105 uses a mobile device 100, in this case a smartphone, to capture digital images of the front 102 of the building 110. In particular, she captures the window 120a located on the front side of the building 110. To do so, it holds the smartphone 100 in a substantially vertical orientation. Simultaneously with capturing the digital images, the smartphone 100 captures a compass direction. The smartphone 100 can thus associate the window 120a with the measured compass direction. Advantageously, therefore, a data set is stored in which both the image of the window, identified dimensions of the window, and the compass direction are stored. The identification of the dimensions of the window can be done either by user input or by automatic capture. For example, automatic detection of the dimensions can be done by a distance measurement by a 3D sensor of the mobile device. In an exemplary embodiment, the mobile device 100 includes processor circuitry that is configured to perform one or more functions and/or operations of the mobile device 100. Further, although exemplary embodiments are described with the mobile device 100 being a smartphone, the mobile device 100 according to the disclosure is not limited thereto and can be other mobile devices as would be understood by one of ordinary skill in the art.

The building has further windows 120b and 120c on another side of the building 104 not facing the street. The mobile device can therefore be used to detect the dimensions and compass direction of the building side from these windows as well.

In particular, the user can thus walk around the building 110 once in order to detect all windows of the building in sequence. Here, it can be provided that the compass direction is determined for each side of the building.

Advantageously, it can be provided that the mobile device carries out an adjustment of the possibly not exactly detected compass directions. For example, if an alignment difference between one side of a building and a next side of a building is not 90°, but deviates from it by a few degrees, it can be assumed that this is a measurement error. Thus, based on the assumption that adjacent building sides are typically at an angle of 90° to each other, a correction of the measured compass directions can be made. For example, it can be provided that such a correction is made for deviations of up to +/−10°. In the case of larger deviations, however, it can be assumed that the sides of the building may not be at right angles to each other. In this case, the user can be prompted to re-measure the sky orientation using the compass of the mobile device in order to exclude a measurement error.

Furthermore, it can be provided that the mobile device simultaneously performs a noise measurement each time a window is recorded. The user can be notified by a signal, for example a symbol on a display of the mobile device, that a noise measurement is being performed. This may prompt the user not to speak or make other sounds during the noise measurement.

Recording of the measured and/or user-entered information may be performed on the mobile device 100 or in the cloud.

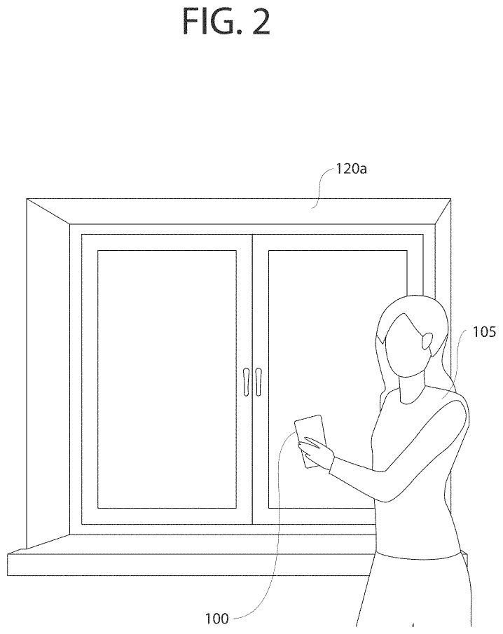

FIG. 2 is a schematic illustration of a capture of further information of a window of a construction project. Here, the user 105 is inside the building and uses the mobile device 100 to capture an image of the window 120a from them and simultaneously take a noise measurement. Thus, a noise measurement in the interior space in front of window 120a can be compared to a noise measurement in the exterior space in front of window 120a. From this difference, an estimate for the sound insulation of an existing window 120a can be determined.

Alternatively, it can be provided that a noise measurement only takes place inside the building, but the user is prompted by the mobile device to perform a measurement with the window open and another measurement with the window closed. Thus, the sound insulation of the existing window structure can be determined.

Likewise, the window area of the window 120a can be determined both from inside and outside using a 3D sensor and/or a 3D sensor in combination with a camera. The multiple-capture has the advantage that the measured values from inside and outside can be matched. In the case of small deviations, the average can be used, or in the case of larger deviations, the user can be prompted by a prompt signal to repeat a measurement because there may be a measurement error.

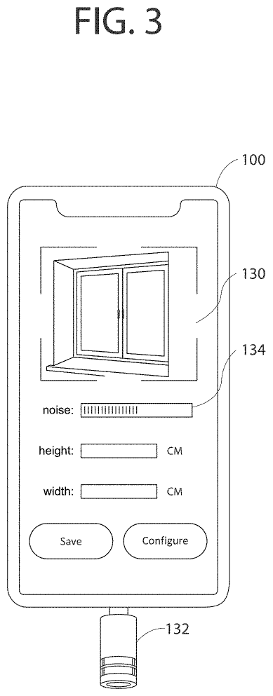

FIG. 3 shows a schematic diagram of a mobile device for capturing information of a construction project, wherein the information includes a noise level. The user interface includes an area 130 where the captured digital image of the window is displayed. This allows the user to ascertain which window information is being captured. The user interface further comprises a level indicator 134, which indicates by different numbers of bars what noise level is currently being measured.

The mobile device 100 of FIG. 3 is a conventional smartphone. Since conventional smartphones are not always suitable for accurate noise level measurement, the smartphone 100 uses a clip-on microphone 132 that plugs into a jack on the microphone, such as a 3.5 mm jack or a USB-C jack.

In other embodiments, the integrated microphone of the smartphone is used. Here, a conversion of the microphone's signal to normalized dB values can be performed using an associative table (based on the known smartphone type).

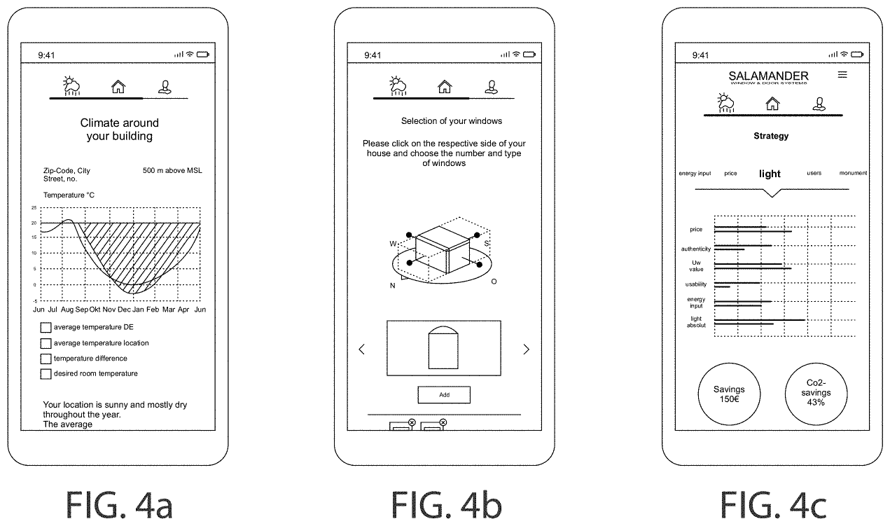

FIG. 4a shows a user interface of the smartphone that displays climate data of an entered location. In particular, an annual history of the average temperature and a difference between the average temperature and the desired room temperature (in this case, 20° C.) are shown. The area between the desired room temperature and the average temperature (as far as it is below the desired room temperature) is shown hatched. The hatched area, in combination with the information about the insulation value of the windows, can thus represent an estimate for the annual heating requirement.

FIG. 4b shows a smartphone user interface for entering the number and type of windows associated with the building sides of the construction project. By clicking on a building side of the symbolic representation of the building, the user can select that building side for input. Thus, the information about the number and type of windows can be entered even if the user is not currently on site at the construction project.

FIG. 4c shows a user interface in which a comparison between the existing windows and the proposed window structure is graphically displayed after the information about the construction project has been collected. In particular, for price, authenticity, Uw value, usability, energy input and light absolute, one bar each is shown for the previous situation and one bar for the situation with the proposed new window structure. Thus, the user gets a quick overview of the advantages of the proposed new window structure.

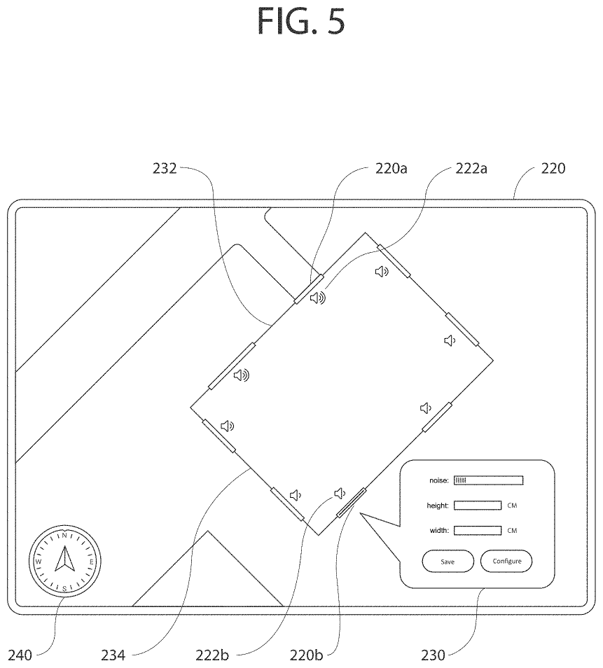

FIG. 5 shows a user interface of a further mobile device, with which in particular a sound situation is detected. This mobile device is a tablet computer 200. A floor plan of a building 210 is shown on the display of the tablet computer 200. In this floor plan, windows 220a, 220b are represented by elongated rectangles. Associated with the windows, symbols 222a, 222b show a noise level at these windows 220a, 220b. The noise levels shown may be noise levels measured by the tablet computer 200 or noise levels estimated based on map information, for example a map service such as Google Maps. Thus, the user gets a quick overview of the windows and the noise level situation of the construction project. Furthermore, the user can enter further information, for example dimensions, about the windows via an input mask 230.

The tablet computer 200 displays on the display the floor plan of the building, such as may be obtained from a mapping service such as Google Maps. The program flow may be such that the mobile device determines the current position via a satellite navigation system such as GPS or Galileo, and then determines which building is closest to this position. This building is then displayed. In a further step, it may be determined in front of which side of the building 232, 234 the mobile device (and thus the user) is located. For example, if the user is standing between the street and the building, the front building side 232 to which the mobile device is closest according to certain current position can be identified as the current building side. This may be indicated (not shown in FIG. 5) by visually highlighting the front building side.

Finally, for this side of the building, the sky orientation can be determined from the floor plan, i.e. on any orientation of the floor plan line of the side of the building relative to the north direction. Thus, a determination of the sky orientation of one or more building sides can also be made a measurement with a compass.

Advantageously, the determination of the sky orientation based on a measurement with a compass of the mobile device can be combined with a determination of the compass direction based on the map service as described above. For example, the compass direction may be determined as the average of the two compass direction determined separately from the compass and the map service. Alternatively, if the compass direction from the compass and map service differ by more than a predetermined threshold, such as 10°, the user may be prompted to repeat the measurement with the compass.

It may further be provided that the method further comprises:
determining a local position of the mobile device by means of a position sensor, determining a compass sky orientation using a compass,
determining one or more map sky alignments of one or more walls of a building near the local position, and
correcting the compass sky orientation based on the one or more map sky orientations.

Thus, the mobile device can determine the local position and determine from information from a map service (e.g., Google Maps) of which building the sky orientation of walls is currently determined. Thus, the compass information can be matched based on map service information. For example, if the compass indicates an orientation of 10°, but the map service indicates an orientation of a nearest wall of the building of 25°, a correction can be made. Especially in cities, compass information is often inaccurate, so the map service information can be preferred. For example, it may be recognized from the map service information that the building is located in an urban area, and then provision may be made to correct the compass information based on the map service. In particular, the user may be asked whether a correction should be made if a discrepancy is detected between compass sky orientations and map sky orientations.

The mobile device 100 and 200 may be equipped with or connected to one or more databases. For example, the mobile device may be equipped with a storage medium on which a database is stored. Alternatively or additionally, the mobile devices may be arranged to communicate with a database, such as a cloud storage database.

The features disclosed in the foregoing description, figures, and claims may be of importance, both individually and in any combination, for the realization of the disclosure in the various embodiments.

To enable those skilled in the art to better understand the solution of the present disclosure, the technical solution in the embodiments of the present disclosure is described clearly and completely below in conjunction with the drawings in the embodiments of the present disclosure. Obviously, the embodiments described are only some, not all, of the embodiments of the present disclosure. All other embodiments obtained by those skilled in the art on the basis of the embodiments in the present disclosure without any creative effort should fall within the scope of protection of the present disclosure.

It should be noted that the terms “first”, “second”, etc. in the description, claims and abovementioned drawings of the present disclosure are used to distinguish between similar objects, but not necessarily used to describe a specific order or sequence. It should be understood that data used in this way can be interchanged as appropriate so that the embodiments of the present disclosure described here can be implemented in an order other than those shown or described here. In addition, the terms “comprise” and “have” and any variants thereof are intended to cover non-exclusive inclusion. For example, a process, method, system, product or equipment comprising a series of steps or modules or units is not necessarily limited to those steps or modules or units which are clearly listed, but may comprise other steps or modules or units which are not clearly listed or are intrinsic to such processes, methods, products or equipment.

References in the specification to “one embodiment,” “an embodiment,” “an exemplary embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The exemplary embodiments described herein are provided for illustrative purposes, and are not limiting. Other exemplary embodiments are possible, and modifications may be made to the exemplary embodiments. Therefore, the specification is not meant to limit the disclosure. Rather, the scope of the disclosure is defined only in accordance with the following claims and their equivalents.

Embodiments may be implemented in hardware (e.g., circuits), firmware, software, or any combination thereof. Embodiments may also be implemented as instructions stored on a machine-readable medium, which may be read and executed by one or more processors. A machine-readable medium may include any mechanism for storing or transmitting information in a form readable by a machine (e.g., a computer). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others.

Further, firmware, software, routines, instructions may be described herein as performing certain actions. However, it should be appreciated that such descriptions are merely for convenience and that such actions in fact results from computing devices, processors, controllers, or other devices executing the firmware, software, routines, instructions, etc. Further, any of the implementation variations may be carried out by a general-purpose computer.

For the purposes of this discussion, the term “processing circuitry” shall be understood to be circuit(s) or processor(s), or a combination thereof. A circuit includes an analog circuit, a digital circuit, data processing circuit, other structural electronic hardware, or a combination thereof. A processor includes a microprocessor, a digital signal processor (DSP), central processor (CPU), application-specific instruction set processor (ASIP), graphics and/or image processor, multi-core processor, or other hardware processor. The processor may be “hard-coded” with instructions to perform corresponding function(s) according to aspects described herein. Alternatively, the processor may access an internal and/or external memory to retrieve instructions stored in the memory, which when executed by the processor, perform the corresponding function(s) associated with the processor, and/or one or more functions and/or operations related to the operation of a component having the processor included therein. In one or more of the exemplary embodiments described herein, the memory is any well-known volatile and/or non-volatile memory, including, for example, read-only memory (ROM), random access memory (RAM), flash memory, a magnetic storage media, an optical disc, erasable programmable read only memory (EPROM), and programmable read only memory (PROM). The memory can be non-removable, removable, or a combination of both.

Reference List

| | |
|---|---|
| 100, 200 | mobile device |
| 105 | user |
| 102 | front side |
| 110, 210 | construction project |
| 120a, 120b, 120c, 220a, 220b | windows |
| 130 | digital image |
| 132 | microphone |
| 134 | level indicator |
| 200 | tablet computer |
| 210 | building |
| 222a, 222b | symbols |
| 230 | input mask |
| 232, 234 | building sides |

1. A computer-implemented method for laying out a window structure on a construction project, comprising:
determining a compass direction of at least one building side of the construction project,
determining window areas of the window structure assigned to building sides of the construction project, and
calculating design parameters of the window structure based on collected data and a database of windows, the collected data including the determined compass direction and the determined windows areas, wherein calculating the design parameters includes optimizing a lighting situation of the construction project.

2. The method of claim 1, wherein the lighting situation comprises an assignment of net glass areas to compass directions, wherein optimizing the lighting situation of the construction project comprises minimizing a deviation of the assignment of the net glass areas to a predetermined ideal distribution, wherein the predetermined ideal distribution comprises a predetermined ideal assignment of net glass areas to basic compass directions.

3. The method according to claim 1, further comprising:
determining a building class of the construction project from a predetermined list of building classes that includes: single-family house, semidetached house, terraced end house, terraced middle house, multi-family house with less than 6 dwelling units, and/or multi-family house with at least 6 dwelling units, and/or determining a construction period of the building,
wherein determining the building class and/or the construction period is based on a digital image of the construction project.

4. The method according to claim 1, wherein calculating the design parameters further comprises optimizing a regional preference situation, the database including a mapping between windows and a regional preference.

5. The method according to claim 1, further comprising:
capturing geographic coordinates of the construction project, and
determining climatic parameters based on the geographic coordinates, the climatic parameters being determined based on an assignment of the geographic parameters to one of several climatic zones,
wherein the calculation of the design parameters is based on the climatic parameters, and the climatic parameters include an annual temperature distribution and/or an annual solar radiation distribution.

6. The method according to claim 1, wherein optimizing the lighting situation comprises:
calculating net glass areas associated with building sides of the construction project, and/or
calculating a ratio of net glass area to a floor area of the construction project and/or a number of stories of the construction project.

7. The method according to claim 1, further comprising:
capturing a digital image of a building side of the construction project, and
automatically identifying one or more windows in the digital image, including estimating a net glass area of the one or more windows.

8. The method of claim 7, wherein the method further comprises:
outputting a first user prompt to prompt a user to bring a mobile device into a horizontal orientation, and/or
outputting a second user prompt to prompt the user to move the mobile device to a vertical orientation.

9. The method according to claim 1, further comprising detecting a noise level in an interior and/or exterior of the construction project, using a microphone of a mobile device, wherein calculating the design parameters includes optimizing a noise situation of the construction project.

10. The method of claim 9, further comprising:
capturing an audio recording and determining the noise level based on the captured audio recording, and identifying a type of a noise captured with the audio recording, wherein optimizing the noise situation of the construction project is performed based on the type of the noise, and/or
determining a time of day and/or day of week, and adjust the noise level based on the time of day and/or day of week.

11. The method according to claim 9, wherein the detection of the noise level is performed using a geo-database on noise sources, including using a map service with information on a course and/or a traffic load of roads.

12. The method according to claim 9, further comprising:
detecting a microphone error corresponding to the microphone being covered by a hand of a user, and
outputting a prompt signal to the user to prompt the user to correct the microphone error.

13. The method according to claim 9, further comprising: normalizing a noise detected by the microphone of the mobile device, wherein the normalization is performed based on assigned types of mobile devices to noise sensitivities of the mobile devices.

14. The method according to claim 1, further comprising: determining a ventilation frequency based on: geographical coordinates, area data, room information, a desired temperature, one or more positions of windows, one or more ventilation positions, and a number of occupants.

15. A non-transitory computer-readable storage medium with an executable program stored thereon, that when executed, instructs a processor to perform the method of claim 1.

16. A mobile device for laying out a window structure on a construction project, comprising:
a compass direction detector configured to detect a compass direction of at least one building side of the construction project,
a window area detector configured to detect window areas of the window structure assigned to building sides of the construction project, and
processing circuitry configured to calculate design parameters of the window structure based on: (a) the detected compass direction and the captured window areas, and (b) a database of windows,
wherein calculating the design parameters includes optimizing a lighting situation of the construction project.

17. The mobile device according to claim 16, wherein the compass direction detector comprises a compass, and/or the window area detector comprises a digital camera.

18. The mobile device according to claim 16, further comprising a microphone configured to detect a noise level in an interior and/or exterior of the construction project.

19. A system for laying out a window structure on a construction project, comprising:
a server configured to perform a prioritization of construction projects based on received captured information and/or usage parameters; and
a mobile device including:
a compass direction detector configured to detect a compass direction of at least one building side of the construction project,
a window area detector configured to detect window areas of the window structure assigned to building sides of the construction project, and
processing circuitry configured to:
calculate design parameters of the window structure based on the detected compass direction and the captured window areas, and a database of windows, wherein calculating the design parameters includes optimizing a lighting situation of the construction project; and
control the mobile device to transmit the captured information and/or usage parameters to the server.
